(19) United States
(12) Patent Application Publication
(10) Pub. No.: US 2025/0253095 A1
(43) Pub. Date: Aug. 7, 2025

(54) METHOD FOR MANUFACTURING AN ELECTRONIC DEVICE

(71) Applicant: TAIYO YUDEN CO., LTD., Tokyo (JP)

(72) Inventors: Ryo ONO, Tokyo (JP); Tetsuhiko FUKUOKA, Tokyo (JP); Shoji KUSUMOTO, Tokyo (JP)

(73) Assignee: TAIYO YUDEN CO., LTD., Tokyo (JP)

(21) Appl. No.: 19/181,199

(22) Filed: Apr. 16, 2025

Related U.S. Application Data
(63) Continuation of application No. 17/988,922, filed on Nov. 17, 2022.

(30) Foreign Application Priority Data
Dec. 10, 2021 (JP) 2021-200626

(51) Int. Cl. H01G 2/06; H01G 4/248; H01G 4/30; H01G 4/38

(52) U.S. Cl. CPC H01G 2/06; H01G 4/248; H01G 4/30; H01G 4/38

(57) ABSTRACT

A circuit board includes a multilayer ceramic electronic component; and a mounting board mounting the multilayer ceramic electronic component thereon, wherein the multilayer ceramic electronic component comprises: a ceramic main body having a dimension in the first axis direction of the ceramic main body of 0.1 mm or more, and a ratio of a dimension in the second axis direction of the ceramic main body to the dimension in the first axis direction of 130% or more, a plurality of internal electrodes laminated inside the ceramic main body in the first axis direction, and both edges of the plurality of internal electrodes in the second axis direction being aligned with each other within 0.5 μm in the second axis direction, and external electrodes respectively covering the end surfaces, and wherein the mounting board faces the second principal surface of the multilayer ceramic electronic component mounted thereon.

### BACKGROUND OF THE INVENTION

### Technical Field

The present invention relates to a technique for suppressing the occurrence of defective mounting of multilayer ceramic electronic components.

### Background Art

In recent years, electronic devices such as personal digital assistants have become more sophisticated and smaller. Along with this, there is a demand for technology that can increase the capacitance of multilayer ceramic capacitors used for power storage and noise reduction in such electronic devices without increasing the mounting area on the mounting surfaces.

On the other hand, there is known a high-profile multilayer ceramic capacitor in which the capacitance is increased by increasing the number of laminated internal electrodes while maintaining the area of each internal electrode (see, for example, Patent Document 1). With such a multilayer ceramic capacitor, although the height on the mounting surface is increased, the mounting space occupied on the mounting surface can be kept small.

In a multilayer ceramic capacitor, the greater the number of laminated internal electrodes, the thinner peripheral portions where the internal electrodes are not provided become, and as a result, peripheral portions of the principal surfaces perpendicular the lamination direction are more rounded. As a result, the principal surface of the multilayer ceramic capacitor is not satisfactorily sucked by the suction nozzle of a chip mounter during mounting, and mounting defects tend to occur.

On the other hand, in the technique described in Patent Document 1, a dielectric member is arranged in a reversed pattern relative to the pattern of the internal electrode. That is, the dielectric member compensates for the thickness of the peripheral portion where the internal electrode is not provided. As a result, in this multilayer ceramic capacitor, both principal surfaces perpendicular to the lamination direction can have high flatness, so that the occurrence of mounting defects as described above can be suppressed.

### RELATED ART DOCUMENT

### Patent Document

Patent Document 1: Japanese Patent Application Laid-Open Publication No. 2020-031152

### SUMMARY OF THE INVENTION

In the multilayer ceramic capacitor described in Patent Document 1, in order to ensure high flatness on both principal surfaces perpendicular to the lamination direction, high precision is required for patterning the dielectrics arranged around the internal electrodes. It is therefore desirable to develop a better technique that can more reliably ensure high flatness on the principal surfaces for high-profile multilayer ceramic capacitors or electronic components.

In view of the circumstances described above, it is an object of the present invention to provide a high-profile multilayer ceramic capacitor/electronic component capable of suppressing the occurrence of mounting defects, a method for manufacturing the same, a circuit board, and a package.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present disclosure provides a circuit board, comprising; a multilayer ceramic electronic component; and a mounting board mounting the multilayer ceramic electronic component thereon, wherein the multilayer ceramic electronic component comprises: a ceramic main body having first and second side surfaces perpendicular to a first axis direction, first and second principal surfaces perpendicular to a second axis direction that is orthogonal to the first axis direction, and first and second end surfaces perpendicular to a third axis direction that is orthogonal to the first and second axis directions, a dimension in the first axis direction of the ceramic main body being 0.1 mm or more, a ratio of a dimension in the second axis direction of the ceramic main body to the dimension in the first axis direction being 130% or more, a plurality of internal electrodes laminated inside the ceramic main body in the first axis direction, each of the plurality of internal electrodes being drawn out to either one of the first and second end surfaces, and both edges of the plurality of internal electrodes in the second axis direction being aligned with each other within 0.5 μm in the second axis direction, and first and second external electrodes respectively covering the first and second end surfaces, and wherein the mounting board has a mounting surface facing the second principal surface of the multilayer ceramic electronic component, and has first and second terminals on the mounting surface that are respectively connected to the first and second external electrodes.

In another aspect, the present disclosure provides a package comprising: a plurality of multilayer ceramic electronic components; and a container accommodating the plurality of multilayer ceramic electronic components therein, wherein each of the plurality of multilayer ceramic electronic components comprises: a ceramic main body including dielectric ceramic layers, the ceramic main body having first and second side surfaces perpendicular to a first axis direction, first and second principal surfaces perpendicular to a second axis direction that is orthogonal to the first axis direction, and first and second end surfaces perpendicular to a third axis direction that is orthogonal to the first and second axis directions, a dimension in the first axis direction of the ceramic main body being 0.1 mm or more, a ratio of a dimension in the second axis direction of the ceramic main body to the dimension in the first axis direction being 130% or more; a plurality of internal electrodes laminated inside the ceramic main body in the first axis direction with the dielectric ceramic layers interposed therebetween, each of the plurality of internal electrodes being drawn out to either one of the first and second end surfaces, and both edges of the plurality of internal electrodes in the second axis direction being aligned with each other within 0.5 μm in the second axis direction; and first and second external electrodes respectively covering the first and second end surfaces, and wherein the container includes a plurality of recesses each accommodating one of the plurality of multilayer ceramic electronic components and each having an opening facing in the second axis direction for extraction of multilayer ceramic electronic component therefrom, the container further having a sealing portion for closing the opening of each of the plurality of recesses.

In another aspect, the present disclosure provides a multilayer ceramic electronic component, comprising: a ceramic main body including dielectric ceramic layers, the ceramic main body having first and second side surfaces perpendicular to a first axis direction, first and second principal surfaces perpendicular to a second axis direction that is orthogonal to the first axis direction, and first and second end surfaces perpendicular to a third axis direction that is orthogonal to the first and second axis directions, a dimension in the first axis direction of the ceramic main body being 0.1 mm or more, a ratio of a dimension in the second axis direction of the ceramic main body to the dimension in the first axis direction being 130% or more, a plurality of internal electrodes laminated inside the ceramic main body in the first axis direction with the dielectric ceramic layers interposed therebetween, each of the plurality of internal electrodes being drawn out to either one of the first and second end surfaces, and both edges of the plurality of internal electrodes in the second axis direction being aligned with each other within 0.5 μm in the second axis direction, and first and second external electrodes respectively covering the first and second end surfaces, wherein one of the first and second principal surfaces is configured as a mounting surface to be mounted on a mounting board, and another of the first and second principal surfaces is configured as a suction surface to be sucked by a suction nozzle.

In another aspect, the present disclosure provides a method for manufacturing a multilayer ceramic electronic component, comprising: forming a laminated sheets that includes a plurality of internal electrodes laminated therein in a first axis direction with dielectric ceramic layers interposed therebetween; cutting through the laminated sheets in the first axis direction so as to form a laminate having first and second cut surfaces that are perpendicular to a second axis direction that is orthogonal to the first axis direction; and forming a ceramic main body having first and second principal surfaces that are perpendicular to the second axis direction by forming first and second margin portions on the first and second cut surfaces of the laminate, respectively, a dimension in the first axis direction of the ceramic main body being 0.1 mm or more, a ratio of a dimension in the second axis direction of the ceramic main body to the dimension in the first axis direction being 130% or more, wherein one of the first and second principal surfaces is configured as a mounting surface to be mounted on a mounting board, and another of the first and second principal surfaces is configured as a suction surface to be sucked by a suction nozzle.

As described above, according to the present invention, it is possible to provide a high-profile multilayer ceramic capacitor/electronic component capable of suppressing the occurrence of mounting defects, a manufacturing method thereof, and a circuit board and a package that have such high profile multilayer ceramic capacitors.

It is to be understood that both the foregoing general description and the following detailed description are exemplary and explanatory, and are intended to provide further explanation of the invention as claimed.

### BRIEF DESCRIPTION OF THE DRAWINGS

FIG. 1 is a perspective view of a multilayer ceramic capacitor according to an embodiment of the present invention.

FIG. 2 is a cross-sectional view of the multilayer ceramic capacitor taken along the line A-A′ in FIG. 1.

FIG. 3 is a cross-sectional view of the multilayer ceramic capacitor taken along the line B-B′ of FIG. 1.

FIG. 4 is a flowchart showing a method for manufacturing the above-mentioned multilayer ceramic capacitor.

FIGS. 5A-5C are plan views of the ceramic sheets prepared in step S01.

FIG. 6 is a perspective view showing step S02.

FIG. 7 is a plan view showing step S03.

FIGS. 8A-8C are partial cross-sectional views showing step S03.

FIG. 9 is a perspective view of an unfired ceramic main body obtained in step S04.

FIG. 10 is a perspective view of a multilayer ceramic capacitor according to a comparative example.

FIG. 11 is a cross-sectional view of the multilayer ceramic capacitor of the comparative example taken along the line C-C′ in FIG. 10.

FIG. 12 is a cross-sectional view of the multilayer ceramic capacitor of the comparative example taken along the line D-D′ in FIG. 10.

FIG. 13 is a partial cross-sectional view showing step S303 in a manufacturing method of the multilayer ceramic capacitor of the comparative example.

FIG. 14 is a schematic diagram of a circuit board according to an embodiment of the present invention;

FIG. 15 is a plan view of a package according to an embodiment of the present invention.

FIG. 16 is a cross-sectional view of the package taken along the line E-E′ of FIG. 15;

FIG. 17 is a diagram showing a manufacturing process of the circuit board.

FIG. 18 is a diagram showing the manufacturing process of the circuit board.

### DETAILED DESCRIPTION OF EMBODIMENTS

Embodiments of the present invention will be described below with reference to the drawings. In the drawings, X-axis, Y-axis, and Z-axis that are orthogonal to each other are shown as appropriate. The X-axis, Y-axis, and Z-axis are common in all drawings.

### Structure of Multilayer Ceramic Capacitor 10

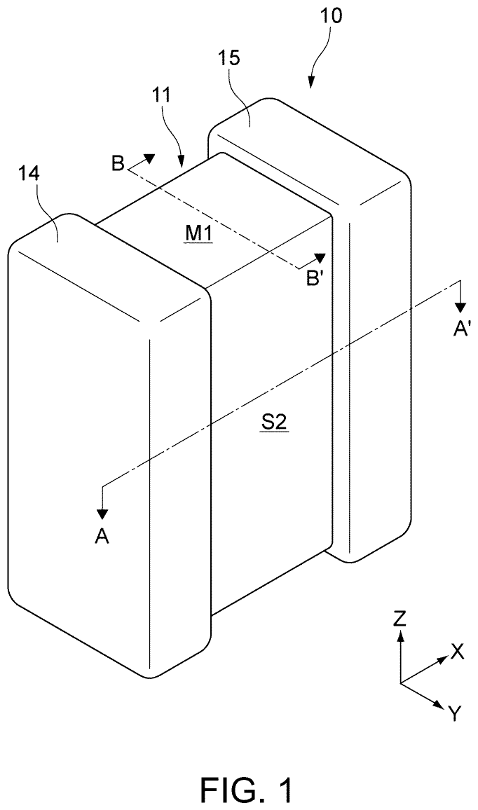

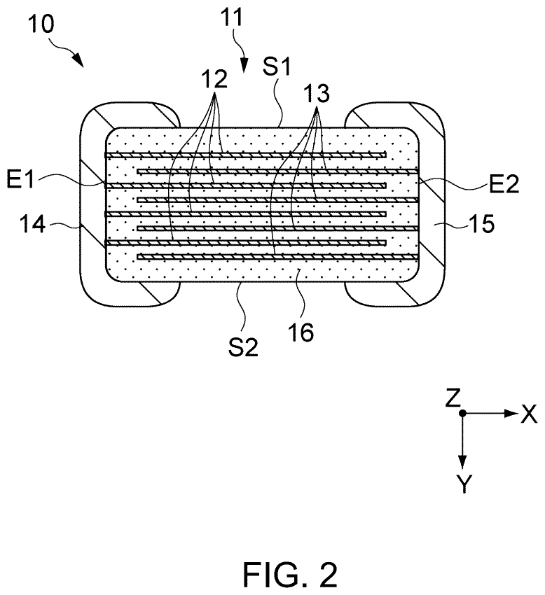

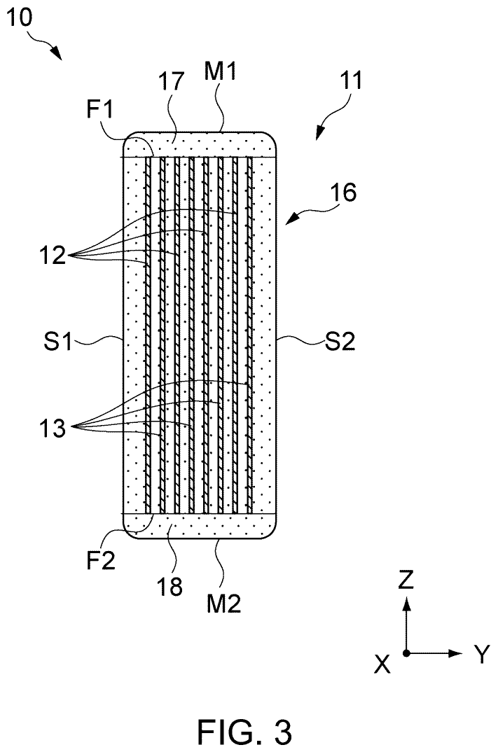

FIGS. 1 to 3 are diagrams showing a multilayer ceramic capacitor 10 according to an embodiment of the present invention. FIG. 1 is a perspective view of the multilayer ceramic capacitor 10. FIG. 2 is a cross-sectional view of the multilayer ceramic capacitor 10 taken along the line A-A′ in FIG. 1. FIG. 3 is a cross-sectional view of the multilayer ceramic capacitor 10 taken along the line B-B′ of FIG. 1.

The multilayer ceramic capacitor 10 includes a ceramic main body 11, a first external electrode 14, and a second external electrode 15. The ceramic main body 11 is constructed as a hexahedron having first and second end surfaces E1 and E2 perpendicular to the X axis, first and second side surfaces S1 and S2 perpendicular to the Y axis, and first and second principal surfaces M1 and M2 perpendicular to the Z axis.

In the multilayer ceramic capacitor 10, the first principal surface M1 of the ceramic main body 11 is a suction surface that is to be suction-held by a suction nozzle of a chip mounter during mounting. In addition, in the multilayer ceramic capacitor 10, the second principal surface M2 of the ceramic main body 11 is a mounting surface facing the mounting surface of the mounting substrate.

The multilayer ceramic capacitor 10 is configured as a tall (high-profile) type in which the dimension T in the Z-axis direction of the ceramic main body 11 is larger than the dimension W in the Y-axis direction of the ceramic main body 11. In other words, the multilayer ceramic capacitor 10 can be mounted in a limited mounting space in the Y-axis direction while securing a large capacity by increasing the dimension T of the ceramic main body 11.

Specifically, in the multilayer ceramic capacitor 10, the ratio T/W of the dimension T to the dimension W is preferably 130% or more. Moreover, in order to secure the stability of the posture when the multilayer ceramic capacitor 10 is mounted on the mounting surface of the mounting substrate, it is preferable that the dimension W be 0.1 mm or more, the dimension L be larger than the dimension W, and the ratio T/W be 200% or less, for example.

The dimension L of the ceramic main body 11 in the X-axis direction is preferably larger than the dimension W, more preferably twice the dimension W or more. Note that the dimension L may be smaller than the dimension T. In the multilayer ceramic capacitor 10, the dimensions T, W, and L of the ceramic main body 11 can be appropriately determined within the range that satisfies the above conditions according to the shape of the mounting space on the mounting surface of the mounting substrate and the required capacitance.

The planar shape along the mounting surface of the multilayer ceramic capacitor 10 is preferably equal to or greater than the 0201 M size, which has a dimension in the X-axis direction of 0.25 mm and a dimension in the Y-axis direction of 0.125 mm. Moreover, the planar shape along the mounting surface of the multilayer ceramic capacitor 10 is preferably equal to or greater than the 1608 M size, which has a dimension in the X-axis direction of 1.6 mm and a dimension in the Y-axis direction of 0.8 mm.

The first and second external electrodes 14, 15 respectively cover the first and second end surfaces E1, E2 of the ceramic main body 11, and extend from the end surfaces E1, E2 to the principal surfaces M1, M2 and the side surfaces S1, S2, respectively. As a result, the external electrodes 14 and 15 each have a U-shape in a cross section separallel to the XZ plane and in a cross section parallel to the XY plane.

The shapes of the external electrodes 14 and 15 are not limited to those shown in FIGS. 1 and 2. For example, the external electrodes 14 and 15 may extend from the respective end surfaces of the ceramic main body 11 to only one of the principal surfaces and have an L-shaped cross section parallel to the XZ plane. Moreover, the external electrodes 14 and 15 do not have to extend to any of the principal surfaces M1 and M2 and the side surfaces S1 and S2.

The external electrodes 14 and 15 are made of a good electrical conductor. Good electrical conductors forming the external electrodes 14 and 15 are, for example, a metal or metal alloy including copper (Cu), nickel (Ni), tin (Sn), palladium (Pd), platinum (Pt), silver (Ag), gold (Au), or the like as a main component.

The ceramic main body 11 is made of a dielectric ceramic and has a laminate 16, a first margin portion 17 and a second margin portion 18. The laminate 16 constitutes the end surfaces E1, E2 and the side surfaces S1, S2 of the ceramic main body 11. Also, the laminate 16 has first and second surfaces F1 and F2 perpendicular to the Z-axis direction.

The margin portions 17 and 18 cover the laminate 16 from above and below in the Z-axis direction; that is, they cover the surfaces F1 and F2 of the laminate 16. Thus, the margin portions 17 and 18 provide the principal surfaces M1 and M2 of the ceramic main body 11, respectively. In the manufacturing process of the multilayer ceramic capacitor 10, the margin portions 17 and 18 are attached to the laminate 16 at a later stage of the manufacture.

The laminate 16 has a laminated structure in which a plurality of ceramic layers are laminated in the Y-axis direction. The laminate 16 has a plurality of sheet-like first and second internal electrodes 12, 13 arranged between a plurality of ceramic layers and extending along the XZ plane. The first and second internal electrodes 12 and 13 are alternately arranged along the Y-axis direction.

The ends of the internal electrodes 12 and 13 in the Z-axis direction are located on the surfaces F1 and F2 of the laminate 16 covered by the margin portions 17 and 18, respectively. Since the surfaces F1 and F2 of the laminate 16 are formed as cut surfaces in the manufacturing process of the multilayer ceramic capacitor 10, the positions of the ends of the internal electrodes 12 and 13 in the Z-axis direction are aligned with each other within 0.5 μm in the Z-axis direction.

The first internal electrodes 12 are drawn out to the first end surfaces E1 and is separated from the second end surface E2. The second internal electrodes 13 are drawn out to the second end surface E2 and is separated from the first end surface E1. Thus, the first internal electrodes 12 are connected only to the first external electrode 14 and the second internal electrodes 13 are connected only to the second external electrode 15.

Therefore, the internal electrodes 12 and 13 are located within the ceramic main body 11 except for the end surfaces El and E2 covered by the external electrodes 14 and 15. This way, in the multilayer ceramic capacitor 10, the internal electrodes 12 and 13 can be physically protected, and insulation between the internal electrodes 12 and 13 can be ensured.

With such a configuration, in the multilayer ceramic capacitor 10, when a voltage is applied between the first external electrode 14 and the second external electrode 15, the voltage is applied between a plurality of ceramic layers that are between the first internal electrodes 12 and the second internal electrodes 13. As a result, electric charges corresponding to the voltage between the first external electrode 14 and the second external electrode 15 are stored in the multilayer ceramic capacitor 10.

In the ceramic main body 11, a dielectric ceramic with a high dielectric constant is used for the ceramic layers in order to increase the capacitance of each ceramic layer between the internal electrodes 12 and 13. Such a dielectric ceramic with a high dielectric constant may be, for example, perovskite structure materials containing barium (Ba) and titanium (Ti), an example of which is barium titanate (BaTiO₃).

The dielectric ceramic may be a composition system, such as strontium titanate (SrTiO₃), calcium titanate (CaTiO₃), magnesium titanate (MgTiO₃), calcium zirconate (CaZrO₃), calcium zirconate titanate (Ca(Zr, Ti)O₃), barium zirconate (BaZrO₃) or titanium oxide (TiO₂).

The internal electrodes 12 and 13 are made of a good electrical conductor. Nickel (Ni) is typically used as such a good electrical conductor forming the internal electrodes 12 and 13. In addition, a metal or metal alloy containing copper (Cu), palladium (Pd), platinum (Pt), silver (Ag), gold (Au) or the like as a main component can be used.

### Manufacturing Method of Multilayer Ceramic Capacitor 10

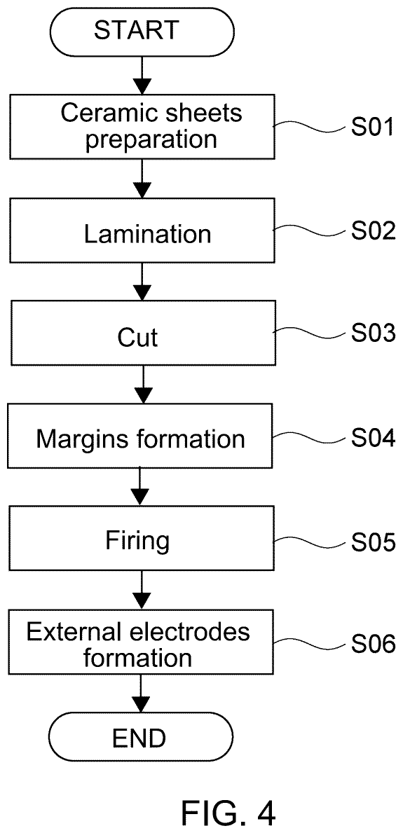

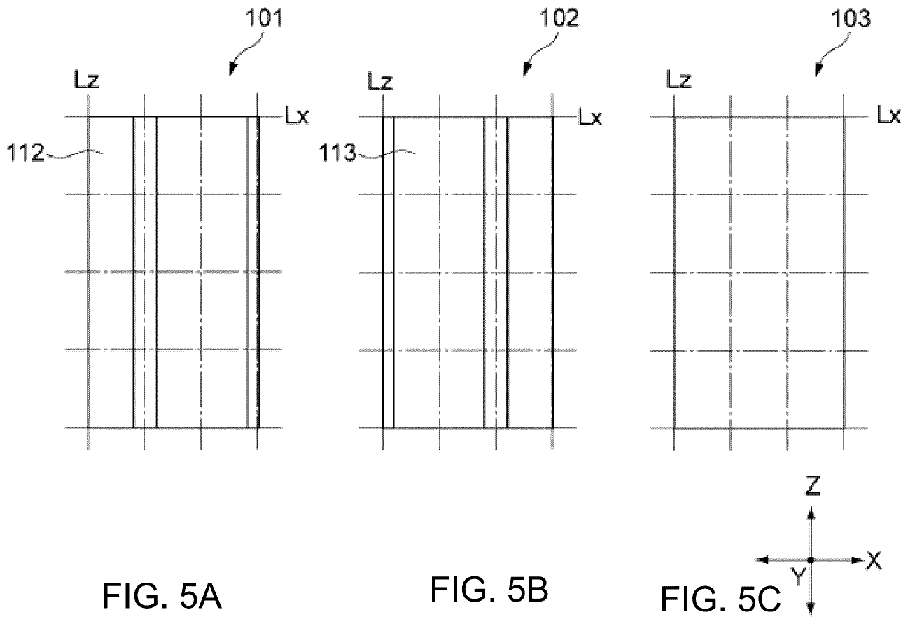

FIG. 4 is a flowchart showing a manufacturing method of the multilayer ceramic capacitor 10 of this embodiment. FIGS. 5A to 9 are diagrams showing the manufacturing process of the multilayer ceramic capacitor 10. Hereinafter, the method for manufacturing the multilayer ceramic capacitor 10 will be described along FIG. 4 with reference to FIGS. 5A to 9 as appropriate.

### Step S01: Ceramic Sheet Preparation

In step S01, first ceramic sheets 101, second ceramic sheets 102, and third ceramic sheets 103 for forming the laminate 16 are prepared. The ceramic sheets 101, 102, 103 are configured as unfired dielectric green sheets containing dielectric ceramics as a main component.

The ceramic sheets 101, 102, 103 are formed into sheets using, for example, a roll coater or a doctor blade. The thickness of ceramic sheets 101 and 102 is adjusted according to the desired thickness of the ceramic layers between internal electrodes 12 and 13 in the multilayer ceramic capacitor 10. The thickness of the third ceramic sheets 103 can be adjusted appropriately.

FIGS. 5A, 5B, and 5C are plan views of the ceramic sheets 101, 102, and 103. At this stage, the ceramic sheets 101, 102, 103 are constructed as large sheets that are not singulated. FIGS. 5A to 5C show cutting lines Lx and Lz for separating into respective multilayer capacitors 10. The cutting lines are parallel to the X-axis, and the cutting lines Lz are parallel to the Z-axis.

As shown in FIGS. 5A and 5B, unfired first internal electrodes 112 for the first internal electrodes 12 are formed on the first ceramic sheet 101, and unfired second internal electrodes 113 for the second internal electrodes 13 are formed on the second ceramic sheet 102. No internal electrodes are formed on the third ceramic sheet 103.

The internal electrodes 112, 113 can be formed by applying an appropriate conductive paste to the ceramic sheets 101, 102. A method for applying the conductive paste can be appropriately selected from known techniques. For example, a screen printing method or a gravure printing method can be used to apply the conductive paste.

Between the respective internal electrodes 112 and 113, gaps extending in the X-axis direction along the cutting lines Lz are formed every other cutting lines Lz. The positions of the gaps between the first internal electrodes 112 and the gaps between the second internal electrodes 113 are alternately arranged in the X-axis direction. That is, the cutting lines Lz passing through the gaps between the first internal electrodes 112 and the cutting lines Lz passing through the gaps between the second internal electrodes 113 are arranged alternately.

### Step S02: Lamination

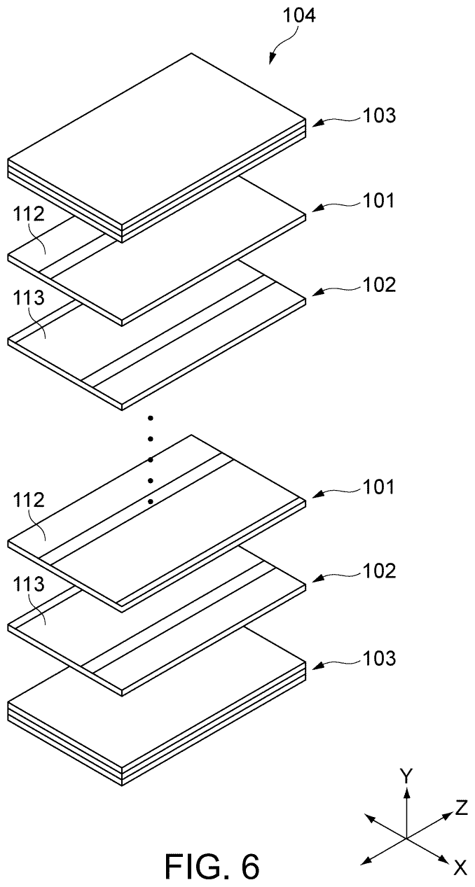

In step S02, the ceramic sheets 101, 102, and 103 prepared in step S01 are laminated as shown in FIG. 6 to produce a laminate 104. In the laminate 104, the first ceramic sheets 101 and the second ceramic sheets 102 are alternately laminated in the Z-axis direction.

Also, in the laminate 104, the third ceramic sheets 103 are laminated from above and below the alternately laminated ceramic sheets 101 and 102 in the Z-axis direction. Although three third ceramic sheets 103 are laminated on the top and on the bottom in the example shown in FIG. 6, the number of third ceramic sheets 103 can be changed as appropriate.

The laminate 104 is formed into a unified piece by pressure bonding the ceramic sheets 101, 102, 103 together. For the pressure bonding of the ceramic sheets 101, 102, 103, it is preferable to use, for example, hydrostatic pressurization or uniaxial pressurization. This way, it is possible to increase the density of the laminate 104.

### Step S03: Cut

In step S03, the laminate 104 obtained in step S02 is cut along the cutting lines Lx and Lz to produce a plurality of unfired laminates 116. The laminate 116 becomes the laminate 16 after firing. For cutting the laminate 104, for example, a press cutting blade or a rotating blade can be used.

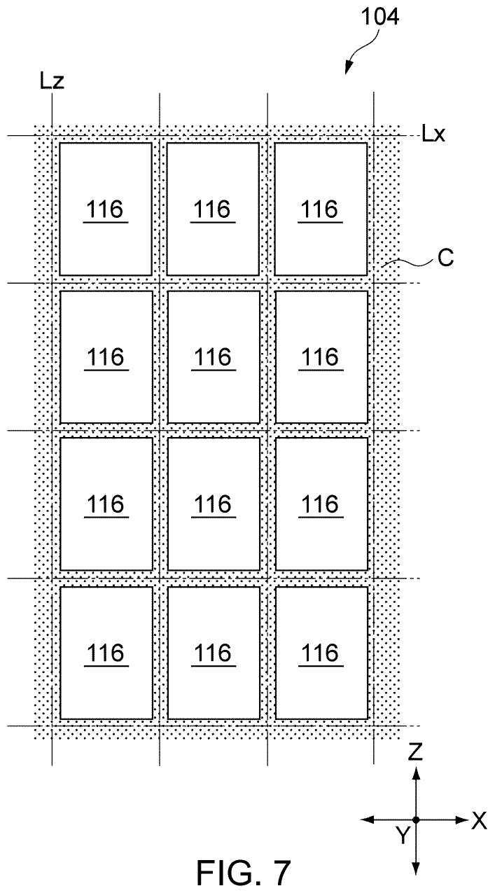

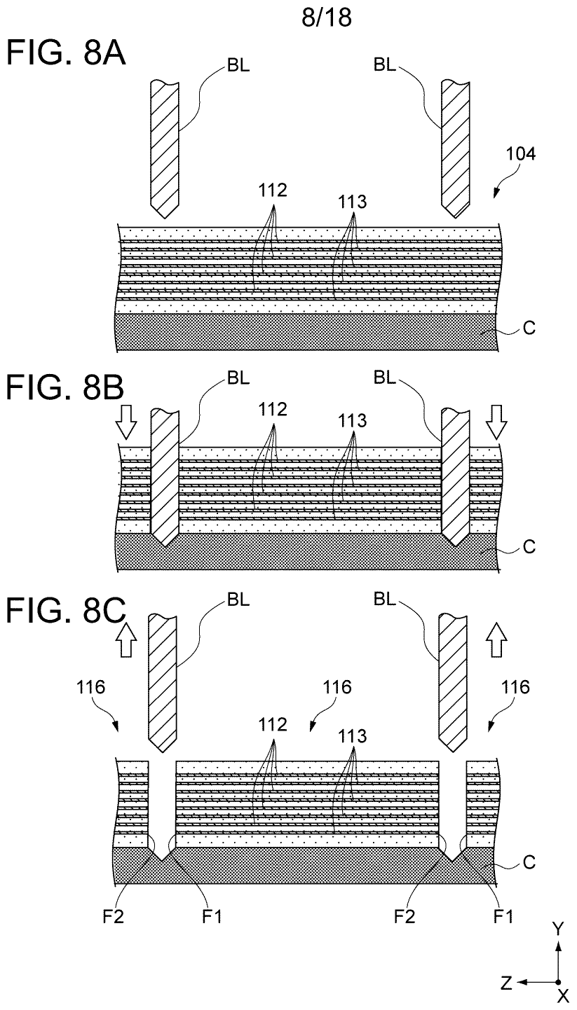

FIGS. 7 and 8A-8C are schematic diagrams for explaining an example of step S03. FIG. 7 is a plan view of the laminate 104. FIG. 8 is a cross-sectional view of the laminate 104 along the YZ plane. The laminate 104 is cut by press cutting blades BL along cutting lines Lx and Lz while being held by an adhesive cut sheet C such as a foam release sheet.

First, as shown in FIG. 8A, the press cutting blades BL are arranged above the laminate 104 in the Y-axis direction, with the tip facing the laminate 104 below in the Y-axis direction. Next, as shown in FIG. 8B, the press cutting blades BL are moved downward in the Y-axis direction until they reach the cut sheet C, thereby penetrating the laminate 104.

Then, as shown in FIG. 8C, the press cutting blades BL are moved upward in the Y-axis direction to pull out from the laminate 104. As a result, the laminate 104 is cut in the X-axis and Z-axis directions so as to form a plurality of laminates 116 having surfaces F1 and F2, which are cut surfaces exposing the internal electrodes 112 and 113 in the Z-axis direction.

### Step S04: Margins Formation

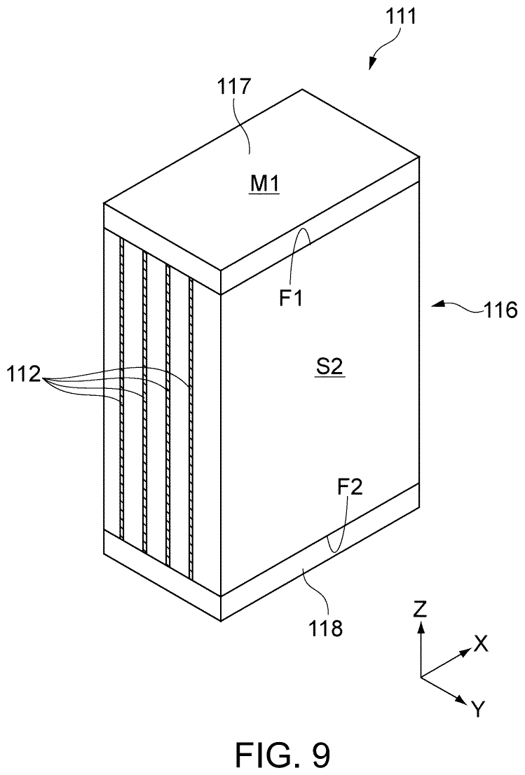

In step S04, each laminate 116 obtained in step S03 is provided with an unfired first margin portion 117 on the first surface F1 and an unfired second margin portion 118 on the second surface F2. As a result, as shown in FIG. 9, an unfired ceramic main body 111 having principal surfaces M1 and M2 formed by margin portions 117 and 118 is obtained.

The margin portions 117 and 118 can be formed by an appropriate method. The margin portions 117 and 118 can be formed using a ceramic sheet, which is a dielectric green sheet, for example. In this case, for example, the ceramic sheet can be punched out by the surface F1/F2 of the laminate 116 or cut into a prescribed shape in advance and attached onto the surfaces F1/F2 of the laminate 116.

### Step S05: Firing

In step S05, the ceramic main body 111 of the multilayer ceramic capacitor 10 shown in FIGS. 1 to 3 is made by firing the ceramic main body 111 shown in FIG. 9 obtained in step S04. In other words, the laminate 116 becomes the laminate 16 and the margin portions 117 and 118 become the margin portions 17 and 18, respectively, by step S05.

The firing temperature in step S05 can be determined based on the sintering temperature of the ceramic main body 111. For example, when using a barium titanate (BaTiO₃)-based material, the firing temperature can be about 1000 to 1300° C. Also, the firing can be performed, for example, in a reducing atmosphere or in a low oxygen partial pressure atmosphere.

### Step S06: External Electrodes Formation

In step S06, external electrodes 14 and 15 are formed on both ends, along the X-axis direction, of the ceramic main body 11 obtained in step S05 to fabricate the multilayer ceramic capacitor 10 shown in FIGS. 1-3. A method for forming the external electrodes 14 and 15 in step S06 can be appropriately selected from known methods.

This completes the multilayer ceramic capacitor 10. In this manufacturing method, since the margin portions 117 and 118 are formed on the surfaces F1 and F2 of the laminate 116 where the internal electrodes 112 and 113 are exposed, edges of the plurality of internal electrodes 12 and 13 in the ceramic main body 11 are aligned within 0.5 μm in the Z-axis direction.

### Multilayer Ceramic Capacitor 10a of a Comparative Example

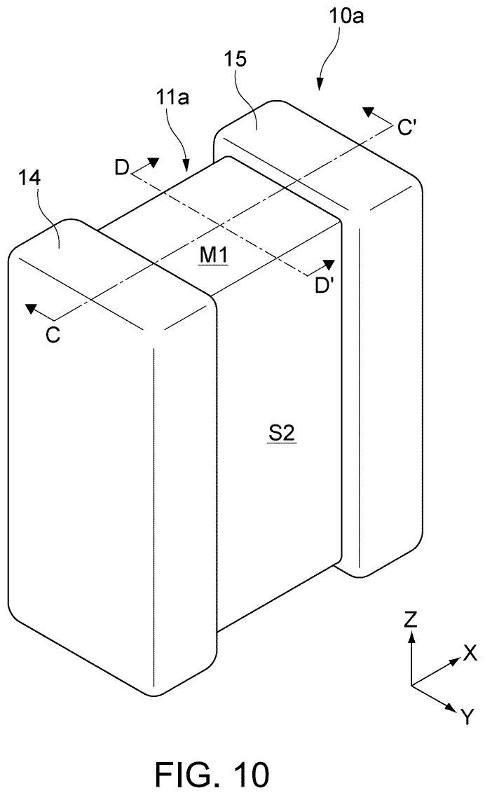

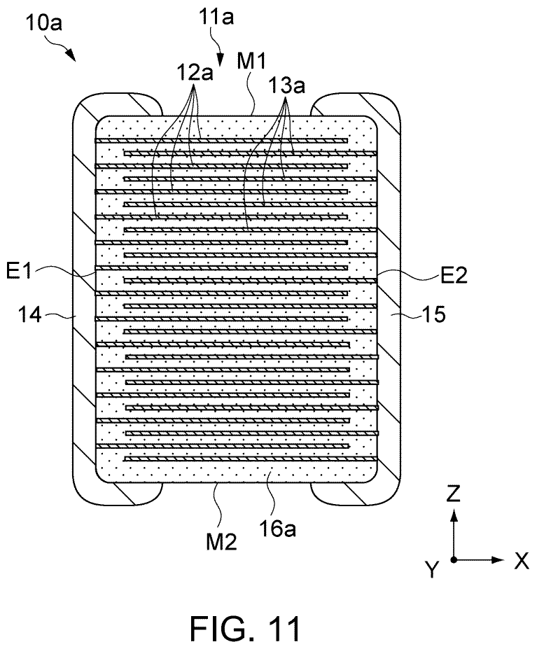

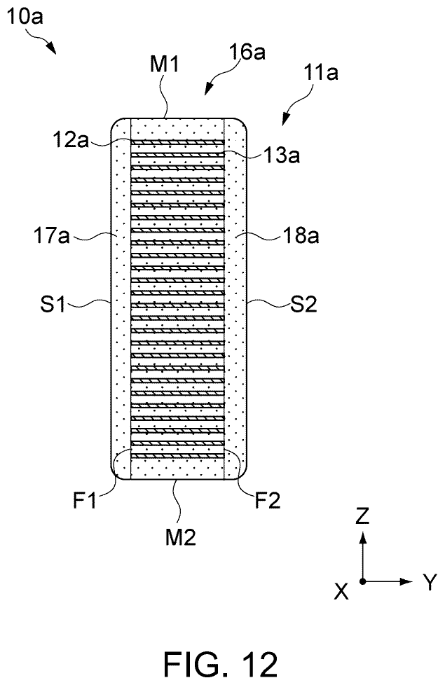

FIGS. 10 to 12 are diagrams showing a multilayer ceramic capacitor 10a according to a comparative example. FIG. 10 is a perspective view of the multilayer ceramic capacitor 10a. FIG. 11 is a cross-sectional view of the multilayer ceramic capacitor 10a taken along the line C-C′ of FIG. 10. FIG. 12 is a cross-sectional view of the multilayer ceramic capacitor 10a taken along the line D-D′ of FIG. 10.

The multilayer ceramic capacitor 10a of the comparative example differs from the above-described embodiment in that a ceramic main body 11a is configured differently from the ceramic main body 11 of the above embodiment. Specifically, in the ceramic main body 11a according to the comparative example, the stacking direction of the ceramic layers in the laminate 16a is the Z-axis direction; that is, the stacking direction of the ceramic layers is different from that for the laminate 16 of the above-described embodiment.

In addition, the multilayer ceramic capacitor 10a of the comparative example has margin portions 17a and 18a that cover the surfaces F1 and F2 of the laminate 16a that are perpendicular to the Y-axis direction. That is, the margin portions 17a and 18a in the comparative example constitute the side surfaces S1 and S2 of the ceramic main body 11a, unlike the margin portions 17 and 18 of the above embodiment.

In the multilayer ceramic capacitor 10a of the comparative example, the total area of the facing regions of the internal electrodes 12a and 13a is increased by increasing the number of layers of the internal electrodes 12a and 13a by the amount corresponding to the increase in the Z-axis direction dimension of the ceramic main body 11a. Because of this, a large capacitance can be obtained in the multilayer ceramic capacitor 10a of the comparative example.

In the ceramic main body 11a of the comparative example, the dimension in the Z-axis direction tends to be relatively smaller at both ends (peripheral regions) along the X-axis direction where one of the internal electrodes 12a and 13a is not provided than at the central portion thereof. In particular, in the ceramic main body 11a, the difference in dimension in the Z-axis direction between the central portion and both ends along the X-axis direction is amplified by the amount of the increase in the number of stacked internal electrodes 12a and 13a.

Therefore, in the ceramic main body 11a of the comparative example, the principal surfaces M1 and M2 functioning as the suction surface and the mounting surface, respectively, tend to have rounded profiles. As a result, in the multilayer ceramic capacitor 10a, mounting defects are likely to occur due to failure of the principal surfaces M1/M2 being satisfactorily sucked by the suction nozzle of the chip mounter for mounting.

In contrast, in the multilayer ceramic capacitor 10 according to the above-described embodiment, the total facing area of the internal electrodes 12 and 13 are increasing by expanding the internal electrodes 12 and 13 in the Z-axis direction by an amount corresponding to the increase in the Z-axis direction dimension T in the ceramic main body 11. Thus, a large capacitance equivalent to that of the multilayer ceramic capacitor 10a according to the comparative example can be obtained.

In addition, in the multilayer ceramic capacitor 10 of the above-described embodiment, the principal surfaces M1 and M2 are provided by the margin portions 17 and 18 covering the surfaces F1 and F2, which are flat cut surfaces. Thus, a high degree of flatness can be obtained for the principal surfaces M1 and M2, which function as the suction surface and the mounting surface, respectively. As a result, the multilayer ceramic capacitor 10 is less prone to mounting defects.

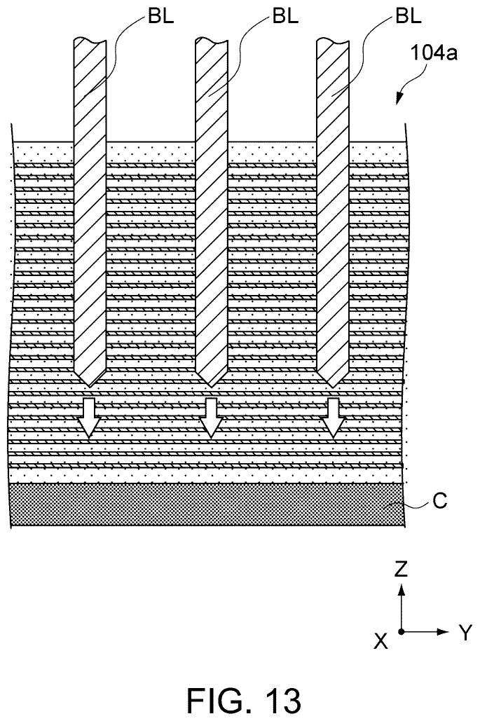

Furthermore, as shown in FIG. 13, which shows a step corresponding to step S03 in the manufacturing process for the multilayer ceramic capacitor 10a of the comparative example, it is necessary to cut through the laminate 104a having a large dimension in the Z-axis direction, which is the lamination direction. Therefore, in this step S03, it is necessary to press the press-cutting blades BL deeply into the laminated sheet 104a in the negative Z-axis direction.

As a result, in the multilayer ceramic capacitor 10a of the comparative example, the surfaces F1 and F2 of the laminated body 16a are likely to be damaged or have a wavy shape along the Z-axis direction. Therefore, the surfaces F1 and F2 of the laminate 16a may not be properly protected by the margin portions 17a and 18a.

In contrast, in step S03 in the manufacturing process of the multilayer ceramic capacitor 10 of the above embodiment, as shown in FIG. 8B, because the laminate 104 has a smaller dimension in the Y axis direction, which is the lamination direction, the amount of penetration by the press-cutting blades BL into the laminate can be kept small. For this reason, in the multilayer ceramic capacitor 10, defects are less likely to occur on the cut surfaces F1 and F2 of the laminate 16.

### Mounting of Multilayer Ceramic Capacitor 10

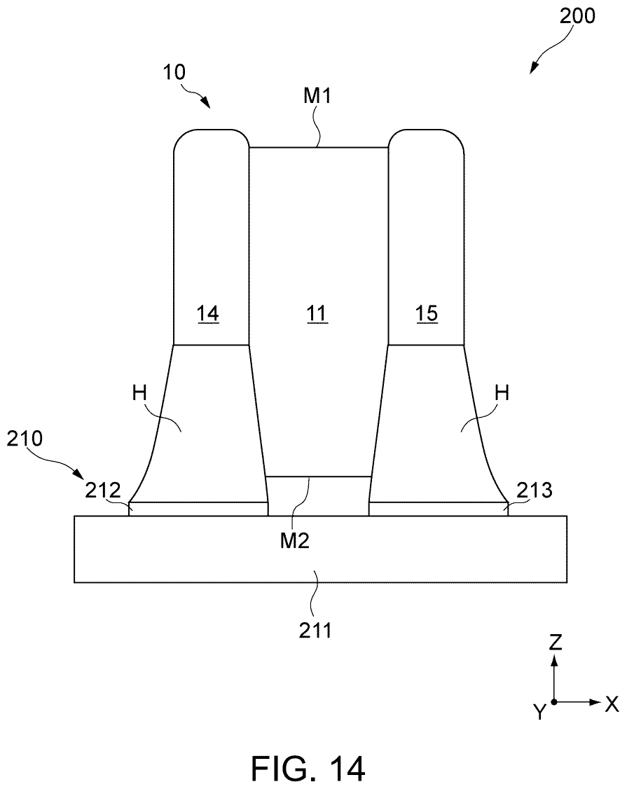

FIG. 14 is a diagram showing a circuit board 200 on which the multilayer ceramic capacitor 10 according to the above embodiment is mounted. The circuit board 200 according to this embodiment includes a mounting board 210. The mounting board 210 has a board body 211 having an upper surface as a mounting surface, and a first terminal 212 and a second terminal 213 provided on the mounting surface of the board body 211.

In the circuit board 200 in which the multilayer ceramic capacitor 10 is mounted on the mounting board 210, the first and second external electrodes 14, 15 are joined to the first and second terminals 212, 213, respectively, via solder H. This way, in the circuit board 200, the multilayer ceramic capacitor 10 is electrically connected to the mounting board 210 and is physically fixed thereto.

An example of a method of mounting the multilayer ceramic capacitor 10 on the mounting board 210 will be described below. The multilayer ceramic capacitor 10 is preferably provided as a package 300 for ease of transportation and storage as well as for continuous mounting. The package 300 preferably accommodates a plurality of multilayer ceramic capacitors 10 in separate compartments.

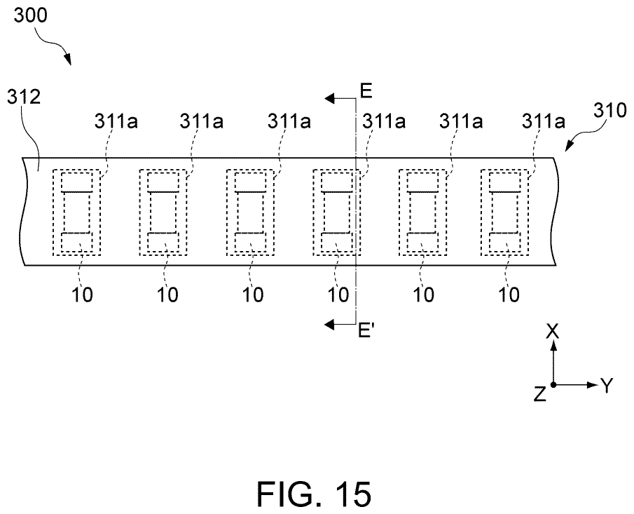

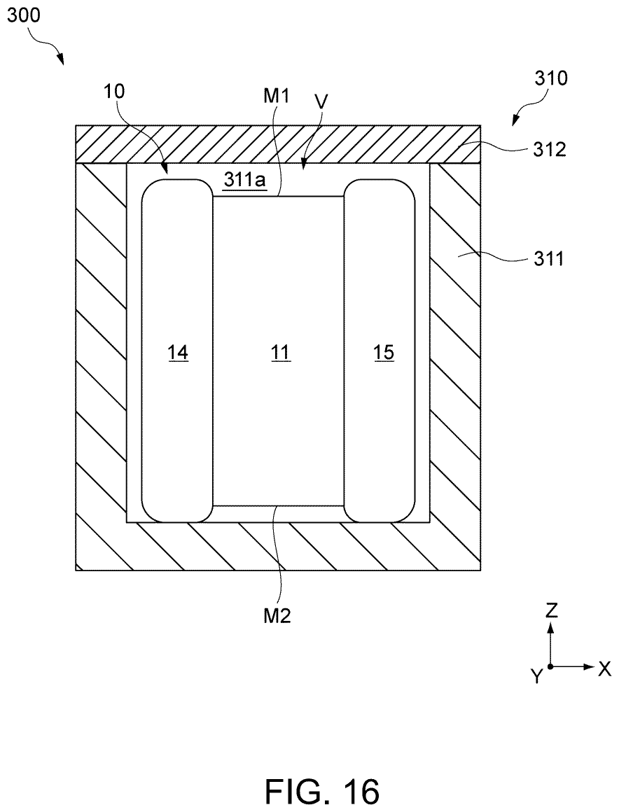

FIGS. 15 and 16 are diagrams showing an example of the package 300 for the multilayer ceramic capacitors 10. FIG. 15 is a plan view of the package 300, and FIG. 16 is a cross-sectional view of the package 300 taken along the line E-E′ of FIG. 15. The package 300 includes a container 310 that houses the multilayer ceramic capacitors 10. The container 310 has a housing portion 311 and a sealing portion 312.

The housing portion 311 includes a plurality of recesses 311a arranged at intervals along the Y-axis direction. Each of the plurality of recesses 311a is provided with an extraction opening V that opens upward in the Z-axis direction. The sealing portion 312 covers the housing portion 311 from above in the Z-axis direction, and closes the extraction openings V of the plurality of recesses 311a at once.

In the container 310, the housing portion 311 is typically configured as a carrier tape, and the sealing portion 312 is typically configured as a cover tape. However, the container 310 is not limited to this structure, and may be configured such that the housing portion 311 is a chip tray having a plurality of recesses in a lattice pattern, and the sealing portion 312 is configured as a lid closing the plurality of the recesses.

One multilayer ceramic capacitor 10 is accommodated in each of the recesses 311a of the housing portion 311. In each of the multilayer ceramic capacitors 10 accommodated in the recess 311a, the first principal surface Ml of the ceramic main body 11, which is the suction surface, faces upwards on the side of the extraction opening V.

When mounting the plurality of multilayer ceramic capacitors 10 in the housing portion 311 on the mounting board 210, the sealing portion 312 is progressively peeled off from the housing portion 311 in the Y-axis direction, and the extraction openings V of the plurality of recesses 311a are sequentially opened. This makes it possible to take out the multilayer ceramic capacitors 10 from the recesses 311a through the respective openings V.

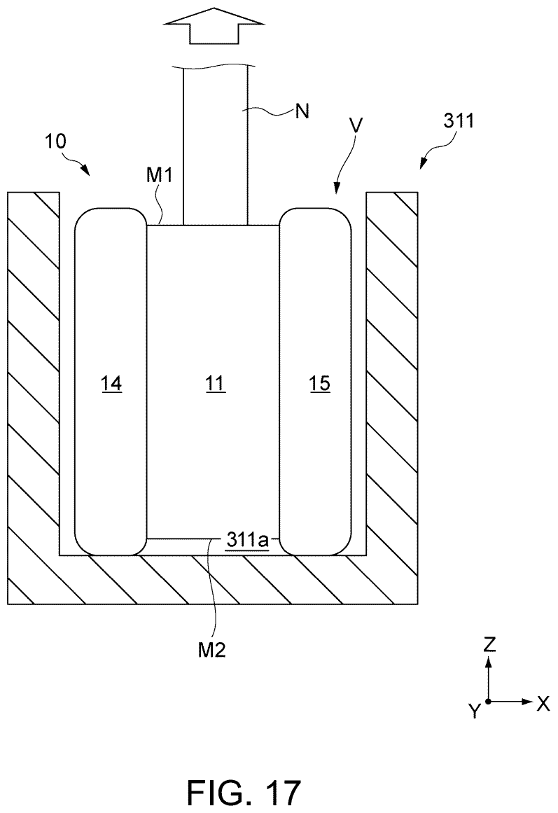

FIG. 17 shows the recess 311a in which the opening V of the housing portion 311 is open. In order to take out the multilayer ceramic capacitor 10 from the recess 311a, a suction nozzle N of a chip mounter is inserted into the recess 311a from above in the Z-axis direction to suck the first principal surface M1, which is the suction surface, of the multilayer ceramic capacitor 10.

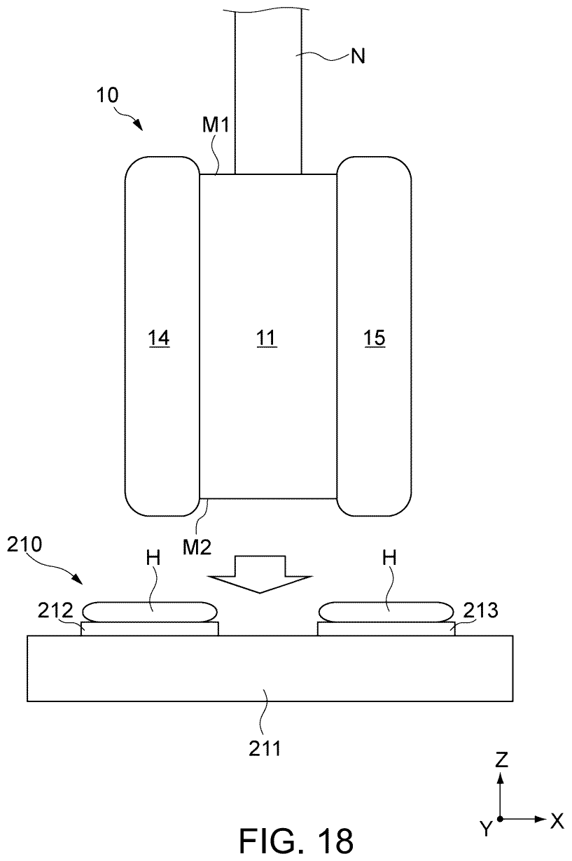

The multilayer ceramic capacitor 10 is stably sucked and held by the suction nozzle N by sufficiently applying the sucking force of the sucking nozzle N to the highly flat first principal surface M1. As shown in FIG. 18, the chip mounter moves the multilayer ceramic capacitor 10 sucked and held by the suction nozzle N to a position above the board body 211 of the mounting board 210.

Then, the chip mounter lowers the multilayer ceramic capacitor 10 downward in the Z axis direction while the external electrodes 14 and 15 are positioned above the terminals 212 and 213, respectively, until the external electrodes 14 and 15 come into contact with the solder H on the terminals 212 and 213, respectively. Then, the suction nozzle N releases the multilayer ceramic capacitor 10.

The multilayer ceramic capacitor 10 disposed on the mounting board 210 is then formed by melting the solder H and solidifying it by, for example, a reflow method, so that the external electrodes 14 and 15 are connected to the terminals 212 and 213 via the solder H, respectively. As a result, the circuit board 200 in which the multilayer ceramic capacitor 10 shown in FIG. 14 is mounted on the mounting board 210 is obtained.

In the multilayer ceramic capacitor 10 according to the present embodiment, not only the first principal surface M1, which is the suction surface, but also the second principal surface M2, which is the mounting surface, has high flatness. Because of this, the stability of the posture of the multilayer ceramic capacitor 10 at the stage before the joining by the solder H is completed can be easily achieved. As a result, mounting defects can be further suppressed in the multilayer ceramic capacitor 10.

### Other Embodiments

Although the embodiments of the present invention have been described above, it goes without saying that the present invention is not limited to the above-described embodiments and can be modified in various ways.

In particular, it will be apparent to those skilled in the art that various modifications and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

For example, in the multilayer ceramic capacitor 10, both the principal surfaces M1 and M2 are highly flat, so the principal surfaces M1 and M2 may function as either the suction surface or the mounting surface. That is, in the multilayer ceramic capacitor 10, contrary to the above embodiment, the first principal surface M1 may be configured as the mounting surface, and the second principal surface M2 may be configured as the suction surface.

Furthermore, in the above embodiment, the multilayer ceramic capacitor 10 was explained as an example of the multiple ceramic electronic component, but the present invention can be applied to multilayer ceramic electronic components in general. Examples of such multilayer ceramic electronic components include chip varistors, chip thermistors, and multilayer inductors.

What is claimed is:

1. A method for manufacturing an electronic device, including a step of mounting a multilayer ceramic electronic component on a circuit board,
wherein the multilayer ceramic electronic component has a ceramic main body and first and second external electrodes, the ceramic main body including internal electrodes and dielectric ceramic layers,
wherein the ceramic main body has first and second side surfaces perpendicular to a first axis direction, first and second principal surfaces perpendicular to a second axis direction that is orthogonal to the first axis direction, and first and second end surfaces perpendicular to a third axis direction that is orthogonal to the first and second axis directions, a first dimension in the first axis direction of the ceramic main body being 0.1 mm or more, a ratio of a second dimension in the second axis direction of the ceramic main body to the first dimension being 130% or more,
wherein the internal electrodes are laminated in the first axis direction with the dielectric ceramic layers interposed therebetween, each of the internal electrodes being drawn out to either one of the first and second end surfaces, and both edges of each of the internal electrodes in the second axis direction being aligned with each other within 0.5 μm in the second axis direction,
wherein the first and second external electrodes covers the first and second end surfaces respectively, and
wherein the step comprises:
sucking the first principal face by a suction nozzle of a chip mounter,
moving the multilayer ceramic electronic component to a predetermined position at which the second principal face faces to a mounting surface of the circuit board while sucking the first principal face,
moving the multilayer ceramic electronic component from the predetermined position toward the mounting surface along the second axis direction until the first and second external electrodes respectively come into contact with first and second terminals on the mounting surface,
releasing the multilayer ceramic electronic component from the suction nozzle after contact of the first and second external electrodes with the first and second terminals, and
connecting the first and second external electrodes to the first and second terminals respectively.

2. The method according to claim 1, wherein, in the sucking the first principal face, the first principal face exposed through an extraction opening of a package housing the multilayer ceramic electronic component is sucked by the suction nozzle.

3. The method according to claim 1, wherein, in the sucking the first principal face, the first principal face on a margin portion of the ceramic main body is sucked by the suction nozzle, the margin portion covering one edge of each of the internal electrodes in the second axis direction.
